(19) United States
(12) Patent Application Publication
(10) Pub. No.: US 2025/0366266 A1
(43) Pub. Date: Nov. 27, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Iuliana RADU, Hsinchu (TW); Hung-Li CHIANG, Hsinchu (TW); Hung-Chi HAN, Hsinchu (TW); Jer-Fu WANG, Hsinchu (TW); Goutham Arutchelvan, Hsinchu (TW); Chao-Ching CHENG, Hsinchu (TW)

(73) Assignee: Taiwan Semiconductor Manufacturing Company, Ltd., Hsinchu (TW)

(21) Appl. No.: 18/672,733

(22) Filed: May 23, 2024

(51) Int. Cl. H01L 33/38; H01L 33/00; H01L 33/06

(52) U.S. Cl. CPC H10H 20/831; H10H 20/014; H10H 20/812; H10H 20/032

(57) ABSTRACT

A semiconductor device includes a substrate and a quantum dot transistor disposed on the substrate and includes a first barrier gate stack, a second barrier gate stack and a first plunger gate stack disposed between the first barrier gate stack and the second barrier gate stack. The first barrier gate stack and the first plunger gate stack are arranged in a first straight axis, the first plunger gate stack and the second barrier gate stack are arranged in a second straight axis, and there is a first angle between the first straight axis and the second straight axis is not equal to 180°.

### BACKGROUND

A conventional quantum dot transistor includes at least one barrier gate stack and least one plunger gate stack. However, at least one barrier gate stack and least one plunger gate stack are generally arranged in a regular matrix, it limits the arrangement of the quantum dot qubit regions in the quantum dot transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a semiconductor device 100 according to an embodiment of the present disclosure;

FIG. 1B illustrates a schematic diagram of a cross-sectional view of the semiconductor device 100 in FIG. 1A along a direction 1B-1B′;

FIG. 2 illustrates a schematic diagram of a cross-sectional view of a local portion of a semiconductor device 200 according to another embodiment of the present disclosure;

FIG. 3 illustrates a schematic diagram of a cross-sectional view of a local portion of a semiconductor device 300 according to another embodiment of the present disclosure; and

FIGS. 4A to 4D illustrate schematic diagrams of manufacturing processes of a semiconductor device 100 according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

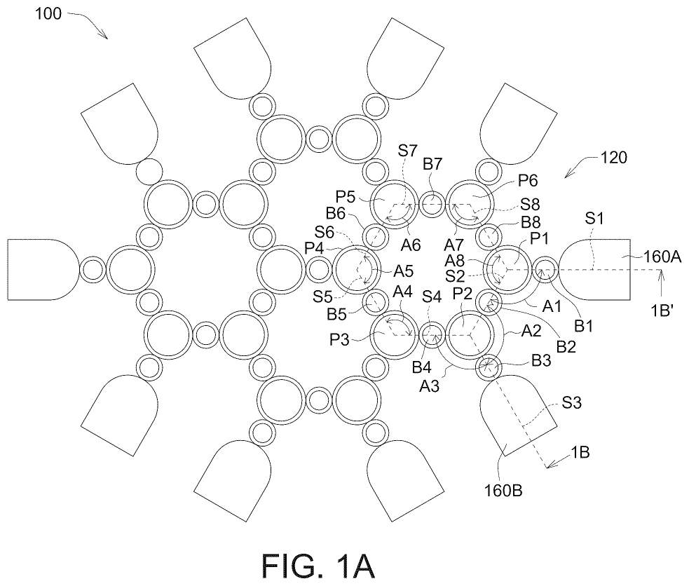

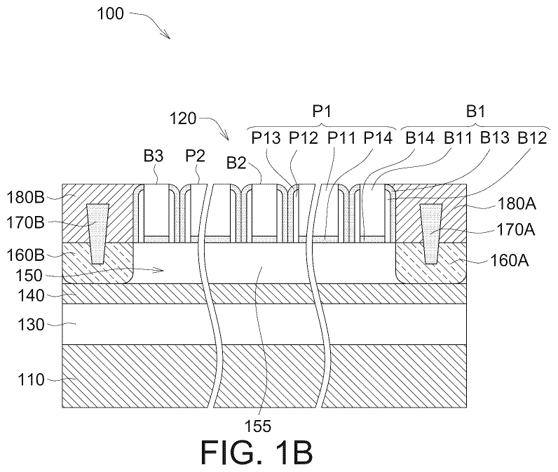

Referring to FIGS. 1A and 1B, FIG. 1A illustrates a schematic diagram of a semiconductor device 100 according to an embodiment of the present disclosure, and FIG. 1B illustrates a schematic diagram of a cross-sectional view of the semiconductor device 100 in FIG. 1A along a direction 1B-1B′.

As illustrated in FIG. 1A, the semiconductor device 100 includes a substrate 110, at least one quantum dot transistor 120, a first silicon germanium (SiGe) layer 130, a silicon layer 140, a quantum dot qubit region 150, a drain region 160A, a source region 160B, a drain contact 170A, a source contact 170B, a first insulation layer 180A and a second insulation layer 180B. The quantum dot transistor 120 is disposed on the substrate 110 and includes at least one barrier (or depletion) gate stack (for example, a first barrier gate stack B1, a second barrier gate stack B2, a third barrier gate stack B3, a fourth barrier gate stack B4, a fifth barrier gate stack B5, a sixth barrier gate stack B6, a seventh barrier gate stack B7 and/or an eighth barrier gate stack B8) and at least one plunger (or accumulation) gate stack (for example, a first plunger gate stack P1, a second plunger gate stack P2, a third plunger gate stack P3, a fourth plunger gate stack P4, a fifth plunger gate stack P5 and/or a sixth plunger gate stack P6).

In an embodiment, one quantum dot transistor 120 may include at least one plunger gate stack and at least one barrier gate stack (optional), and/or two quantum dot transistors 120 may share at least one gate stack.

As illustrated in FIG. 1A, at least one barrier gate stack and at least one plunger gate stack may be arranged in two straight axes which are connected in non-parallel. For example, at least one barrier gate stack and at least one plunger gate stack may be arranged as at least one portion of a honeycombed shape, or arranged as at least one polygonal shape. In the present embodiment, the barrier gate stacks and the plunger gate stacks may be arranged in a two-dimensional quantum dot array in a honeycomb structure.

As illustrated in FIG. 1A, in an embodiment, the first plunger gate stack P1 is disposed between the first barrier gate stack B1 and the second barrier gate stack B2. The first barrier gate stack B1 and the first plunger gate stack P1 are arranged in a first straight axis S1, the first plunger gate stack P1 and the second barrier gate stack B1 are arranged in a second straight axis S2, and there is a first angle Al between the first straight axis S1 and the second straight axis S2 is not equal to 180° or is not 0°.

As illustrated in FIG. 1A, the drain region 160A (or the drain contact 170A and the first insulation layer 180A), the first barrier gate stack B1 and the first plunger gate stack P1 may be arranged in the first straight axis S1. The first plunger gate stack P1, the second barrier gate stack B2 and the second plunger gate stack P2 may be arranged in the second straight axis S2.

As illustrated in FIG. 1A, in another embodiment, the second plunger gate stack P2 is disposed between the second barrier B2 and the third barrier gate stack B3, the second plunger gate stack P2 and the third barrier gate stack B3 are arranged in a third straight axis S3, and there is a second angle A2 between the second straight axis S2 and the third straight axis S3 is not equal to 180° or is not 0°.

As illustrated in FIG. 1A, the second region 160B, the second plunger gate stack P2 and the third barrier gate stack B3 may be arranged in the third straight axis S3.

As illustrated in FIG. 1A, in another embodiment, the second plunger gate stack P2 is disposed between the second barrier B2 and the fourth barrier gate stack B4, the second plunger gate stack P2 and the fourth barrier gate stack B4 are arranged in a fourth straight axis S4, and there is a third angle A3 between the second straight axis S2 and the fourth straight axis S4 is not equal to 180° or is not 0°.

As illustrated in FIG. 1A, the second plunger gate stack P2, the fourth barrier gate stack B4 and the third plunger gate stack P3 may be arranged in the fourth straight axis S4.

As illustrated in FIG. 1A, in another embodiment, the second plunger gate stack P2 is disposed between the second barrier B2 and the fourth barrier gate stack B4, the second plunger gate stack P2 and the fourth barrier gate stack B4 are arranged in a fourth straight axis S4, and there is a third angle A3 between the second straight axis S2 and the fourth straight axis S4 is not equal to 180° or is not 0°. In an embodiment, the third angle A3 is, for example, 60°.

As illustrated in FIG. 1A, in another embodiment, the third plunger gate stack P3 is disposed between the fourth barrier gate stack B4 and the fifth barrier gate stack B5, the third plunger gate stack P3 and the fifth barrier gate stack B5 are arranged in a fifth straight axis S5, and there is a fourth angle A4 between the fourth straight axis S4 and the fifth straight axis S5 is not equal to 180° or is not 0°. In an embodiment, the fourth angle A4 is, for example, 60°.

As illustrated in FIG. 1A, the third plunger gate stack P3, the fourth barrier gate stack B4 and the fifth plunger gate stack P5 may be arranged in the fifth straight axis S5.

As illustrated in FIG. 1A, in another embodiment, the fourth plunger gate stack P4 is disposed between the fifth barrier gate stack B5 and the sixth barrier gate stack B6, the fourth plunger gate stack P4 and the sixth barrier gate stack B6 are arranged in a sixth straight axis S6, and there is a fifth angle A5 between the fifth straight axis S5 and the sixth straight axis S6 is not equal to 180° or is not 0°. In an embodiment, the fifth angle A5 is, for example 60°.

As illustrated in FIG. 1A, the fourth plunger gate stack P4, the sixth barrier gate stack B6 and the fifth plunger gate stack P5 may be arranged in the sixth straight axis S6.

As illustrated in FIG. 1A, in another embodiment, the fifth plunger gate stack P5 is disposed between the sixth barrier gate stack B6 and the seventh barrier gate stack B7, the fifth plunger gate stack P5 and the seventh barrier gate stack B7 are arranged in a seventh straight axis S7, and there is a sixth angle A6 between the sixth straight axis S6 and the seventh straight axis S7 is not equal to 180° or is not 0°. In an embodiment, the sixth angle A6 is, for example 60°.

As illustrated in FIG. 1A, the fifth plunger gate stack P5, the seventh barrier gate stack B7 and the sixth plunger gate stack P6 may be arranged in the seventh straight axis S7.

As illustrated in FIG. 1A, the sixth plunger gate stack P6 is disposed between the seventh barrier gate stack B7 and the eighth barrier gate stack B8, the sixth plunger gate stack P6 and the eighth barrier gate stack B8 are arranged in an eighth straight axis S8, and there is a seventh angle A7 between the seventh straight axis S7 and the eighth straight axis S8 is not equal to 180° or is not 0°. In an embodiment, the seventh angle A7 is, for example 60°.

As illustrated in FIG. 1A, the sixth plunger gate stack P6, the eighth barrier gate stack B8 and the first plunger gate stack P1 may be arranged in the eighth straight axis S8.

As described above, at least plunger gate stack and at least barrier gate stack may be arranged in one straight axis, and/or at least two gate stacks may be arranged in one straight axis.

As illustrated in FIG. 1B, the substrate 110 is, for example, a portion of a silicon wafer. The SiGe layer 130 is formed between the substrate 110 and the silicon layer 140. The silicon layer 140 is formed between the SiGe layer 130 and a channel region 116. The barrier gate stacks, the plunger gate stacks are formed on the substrate 110. The drain contact 170A and the first insulation layer 180A are formed on the drain region 160A, and the drain contact 170A is connected to the drain region 160A and forms an ohmic contact at the interface between the drain contact 170A and the drain region 160A. The source contact 170B and the first insulation layer 180A are formed on the source region 160B, and the source contact 170B is connected to the source region 160B and forms an ohmic contact at the interface between the source contact 170B and the source region 160B. In some embodiments, the source contact 170B and the drain contact 170A may be conductive materials as well.

The channel region 155 is disposed in the substrate 110 and between the source region 160B and the drain region 160A. The barrier gate stacks are disposed over the channel region 155 and define a quantum dot qubit region 150 in the channel region 155 and between the barrier gate stacks B1 and B3. The barrier gate stack may generate an energy barrier to limit the movement of carrier in the quantum dot qubit region 150. In some embodiments, the quantum dot qubit region 150 allows only a single carrier (electron or hole) passing from an entrance of the quantum dot qubit region 150 (i.e., a region beneath the barrier gate stack B3) to an exit of the quantum dot qubit region 150 (i.e., a region beneath the barrier gate stack B1) before another carrier moves into the quantum dot qubit region 150. The plunger gate stack is disposed between the barrier gate stack B1 and B3 and covers the channel region 155.

In some embodiments, the substrate 110 and the channel region 155 are both of a first conductivity type, and the source region 160B and the drain region 160A are both of a second conductivity type opposite to the first conductivity type. For example, the substrate 110 is a p-type silicon substrate (p-substrate). P-type dopants may be introduced into the substrate 110 to form the p-substrate. The channel region 155 is a p-type region and has a dopant concentration greater than a dopant concentration of the substrate 110. The source region 160B and the drain region 160A are both n-type regions. In some other embodiments, both the substrate 110 and the channel region 155 are n-type, and both the source region 160B and the drain region 160A are p-type.

As illustrated in FIG. 1B, each barrier gate stack includes a gate portion B11, a gate spacer B12, a gate isolation portion B13 and a gate dielectric portion B14. The gate dielectric portion B14 is formed between the gate portion B11 and the channel region 155. The gate spacer B12 is formed on a first portion of a sidewall of the gate portion B11. The gate isolation portion B13 covers a sidewall of the gate spacer B12 and a second portion of the sidewall of the gate portion B11.

In some embodiments, the gate portion B11 may be formed of a conductive material including W, Ti, TiAlC, Al, TiAl, TaN, TaAlC, TiN, TiC, Co, TaC, Al, TiAl, HfTi, TiSi, TaSi, TiAlC, combinations thereof, or the like.

As illustrated in FIG. 1B, each plunger gate stack includes a gate portion P11, a gate spacer P12, a gate isolation portion P13 and a gate dielectric portion P14. The gate dielectric portion P14 is formed between the gate portion P11 and the channel region 155. The gate spacer P12 is formed on a first portion of a sidewall of the gate portion P11. The gate isolation portion P13 covers a sidewall of the gate spacer P12 and a second portion of the sidewall of the gate portion P11. In some embodiments, the gate spacer P12 may be formed of a conductive material similar to or the same as that of the gate portion B11.

The gate portion B11 is separated by barriers and cover the entirety of the SiGe layer (or quantum dot qubit region) 150. In some embodiments, a high voltage is applied to the gate portion B11 during the operation to turn on the channel region by inducing an inversion layer on the top surface of the channel region, so the gate portion B11 is designed to be thick enough to bear the high voltage. In some embodiments, the gate portion B11 has a thickness ranging from about 30 nm to about 100 nm.

In an embodiment, the barrier gate stacks and the plunger gate stacks may be arranged in a line, wherein the line includes or is composed of at least one straight axis, at least one curved axis or a combination thereof. In an embodiment, the barrier gate stacks and the plunger gate stacks may be arranged in a polygonal shape, a circular shape or an elliptical shape. In other embodiment, the barrier gate stacks and the plunger gate stacks may be arranged in a non-regular shape.

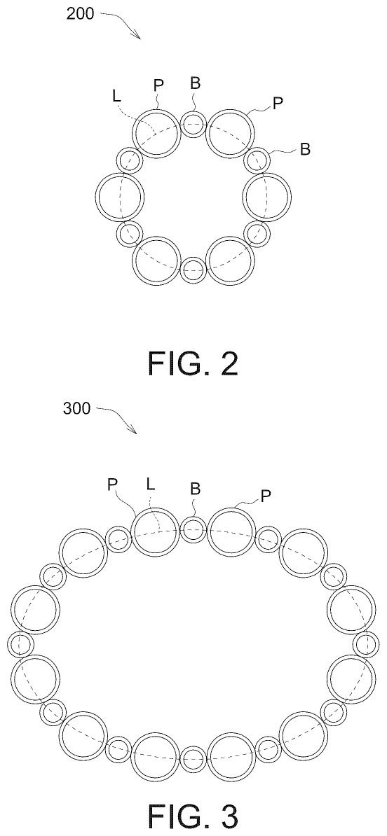

Referring to FIG. 2, FIG. 2 illustrates a schematic diagram of a cross-sectional view of a local portion of a semiconductor device 200 according to another embodiment of the present disclosure. The semiconductor device 200 includes feature similar to or the same as that of the semiconductor device 100, and at least difference is that the barrier gate stacks B and the plunger gate stacks P may be arranged in a line L, wherein the line L is, for example, a circular shape.

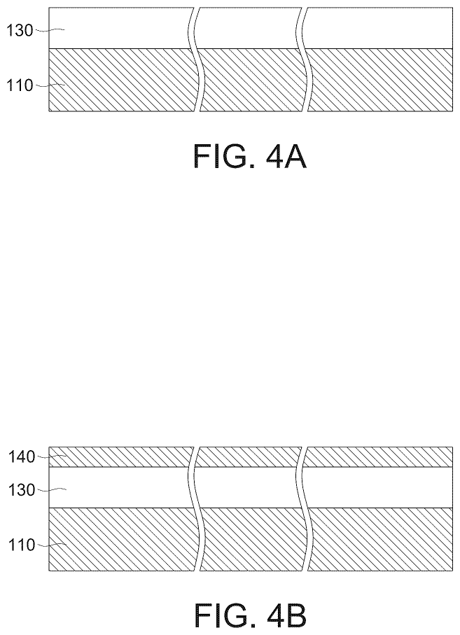

Referring to FIG. 3, FIG. 3 illustrates a schematic diagram of a cross-sectional view of a local portion of a semiconductor device 300 according to another embodiment of the present disclosure. The semiconductor device 200 includes feature similar to or the same as that of the semiconductor device 100, and at least difference is that the barrier gate stacks B and the plunger gate stacks P may be arranged in a line L, wherein the line L is, for example, an elliptical shape.

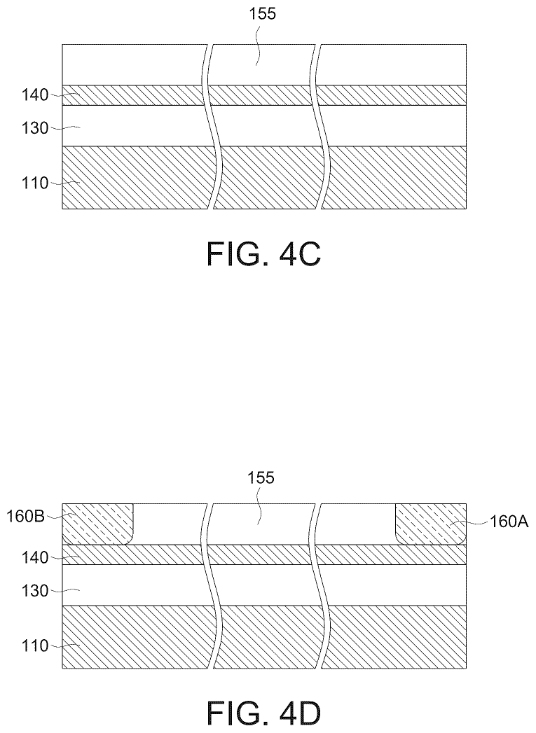

Referring to FIGS. 4A to 4D, FIGS. 4A to 4D illustrate schematic diagrams of manufacturing processes of a semiconductor device 100 according to an embodiment of the present disclosure.

As illustrated in FIG. 4A, a substrate 110 is provided. In some embodiments, the substrate 110 includes silicon or is a silicon wafer. Alternatively, the substrate 110 may include germanium (Ge), silicon germanium (SiGe), gallium arsenide (GaAs), or other appropriate semiconductor materials. In some alternative embodiments, the substrate 110 includes an epitaxial layer with or without dopants. Furthermore, the substrate 110 may include a semiconductor-on-insulator (SOI) structure having a buried dielectric layer therein. In some embodiments, the substrate 110 includes a p-type silicon substrate (p-substrate) or n-type silicon substrate (n-substrate). Then, the SiGe layer 130 may be formed on the substrate by, for example, deposition.

As illustrated in FIG. 4B, the silicon layer 140 may be formed on the SiGe layer 130 by, for example, deposition.

As illustrated in FIG. 4C, a SiGe layer may be formed on the silicon layer 140 by, for example, deposition. Then, an implantation process is performed to introduce first impurities into the substrate 110 to form the channel region 155 in the substrate 110. The first impurities may be p-type impurities or n-type impurities. The n-type impurities may be phosphorus, arsenic, or the like, and the p-type impurities may be boron, BF₂, or the like. For example, the channel region 155 is a p-type region formed in the p-substrate.

As illustrated in FIG. 4D, another implantation process is then performed to introduce second impurities into the well region to form the drain region 160A and the source region 160B. The second impurities may be n-type impurities or p-type impurities. The n-type impurities may be phosphorus, arsenic, or the like, and the p-type impurities may be boron, BF₂, or the like. For example, the drain region 160A and the source region 160B are n-type regions formed in the p-type well region, such that the channel region is formed between the drain region 160A and the source region 160B.

Then, a gate dielectric portion layer and a gate portion layer are sequentially formed over the channel region 155 in FIG. 4C.

In some embodiments, the gate dielectric portion layer includes silicon dioxide, silicon nitride, or other suitable material. Alternatively, the gate dielectric portion layer may be a high-κ dielectric layer having a dielectric constant (κ) higher than the dielectric constant of SiO2, i.e. κ>3.9. The gate dielectric portion layer may include LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr) TiO₃ (BST), Al₂O₃, Si₃N₄, oxynitrides (SiON), or other suitable materials. The gate dielectric portion layer is deposited by suitable techniques, such as ALD, CVD, PVD, thermal oxidation, combinations thereof, or other suitable techniques.

In some embodiments, the gate portion layer may be formed by physical vapor deposition (PVD) including sputtering, chemical vapor deposition (CVD), atomic layer deposition (ALD) or other suitable method.

Then, the gate portion layer and the gate dielectric portion layer are patterned, by using the patterned photoresist layer as an etch mask, to form a plurality of the gate portions (for example, B11 and P11) and a plurality of the gate dielectric portions (for example, B14 and P14). In some embodiments, the etching process is a dry etching process with etching gases CF₄, SF₆, combinations thereof, or the like. After the etching process, the patterned photoresist layer is removed, and the removal method may be performed by solvent stripping or plasma ashing, for example. The gate portions and the gate dielectric portions are formed between the drain region 160A and the source region 160B.

In some embodiments, the source region 160B, the drain region 160A, the channel region 155, the barrier gate stacks and the plunger gate stacks form a quantum dot transistor on a side of the substrate. The quantum dot qubit region 150 is arranged in a one-dimensional or two-dimensional array, such as a 6×6 qubit array or other arrangements.

Then, at least one gate spacer (for example, B12 and P12) is formed, by deposition, lithography process, etc., on a lateral surface of the corresponding gate portion and gate dielectric portion. Then, at least one gate isolation portion (for example, B13 and P13) is formed, by deposition, lithography process, etc., on a lateral surface of the corresponding gate spacer. The gate portions are spaced apart from each other by the corresponding gate isolation portion.

In some embodiments, the source region 160B, the drain region 160A, the channel region (for example, a region between the source region 160B and the drain region 160A), the gate portions, the gate spacers and the gate portions form the quantum dot transistor on the substrate 110.

Next, the first insulation layer 180A and the second insulation layer 180B are formed over the substrate 110 and cover the quantum dot transistor. Furthermore, the first insulation layer 180A and the second insulation layer 180B may be formed of a material that includes an oxide material, such as, silicon oxide, silicon nitride, or the like.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes at least one quantum dot transistor. The quantum dot transistor includes a plurality of barrier gate stacks and a plurality of plunger gate stacks. The barrier gate stacks and the plunger gate stacks may be arranged in a line composed of a straight axis, a curved axis or a combination thereof. As a result, it may increase configuration/design flexibility of the quantum dot qubit regions in the quantum dot transistor.

Example embodiment 1: a semiconductor device includes a substrate and a quantum dot transistor disposed on the substrate and includes a first barrier gate stack, a second barrier gate stack and a first plunger gate stack disposed between the first barrier gate stack and the second barrier gate stack. The first barrier gate stack and the first plunger gate stack are arranged in a first straight axis, the first plunger gate stack and the second barrier gate stack are arranged in a second straight axis, and there is a first angle between the first straight axis and the second straight axis is not equal to 180°.

Example embodiment 2 based on Example embodiment 1: the quantum dot transistor further includes a second plunger gate stack and a third barrier gate stack. The second plunger gate stack is disposed between the second barrier and the third barrier gate stack, the second plunger gate stack and the third barrier gate stack are arranged in a third straight axis, and there is a second angle between the second straight axis and the third straight axis is not equal to 180°.

Example embodiment 3 based on Example embodiment 1: the quantum dot transistor further includes a second plunger gate stack and a fourth barrier gate stack. The second plunger gate stack is disposed between the second barrier and the fourth barrier gate stack, the second plunger gate stack and the fourth barrier gate stack are arranged in a fourth straight axis, and there is a third angle between the second straight axis and the fourth straight axis is not equal to 180°.

Example embodiment 4 based on Example embodiment 3: the third angle is 60°.

Example embodiment 5 based on Example embodiment 1: the quantum dot transistor further includes a third plunger gate stack and a fifth barrier gate stack. The third plunger gate stack is disposed between the fourth barrier gate stack and the fifth barrier gate stack, the third plunger gate stack and the fifth barrier gate stack are arranged in a fifth straight axis, and there is a fourth angle between the fourth straight axis S4 and the fifth straight axis is not equal to 180°.

Example embodiment 6 based on Example embodiment 5: the fourth angle is 60°.

Example embodiment 7 based on Example embodiment 5: the quantum dot transistor further includes a fourth plunger gate stack and a sixth barrier gate stack. The fourth plunger gate stack is disposed between the fifth barrier gate stack and the sixth barrier gate stack, the fourth plunger gate stack and the sixth barrier gate stack are arranged in a sixth straight axis, and there is a fifth angle between the fifth straight axis and the sixth straight axis is not equal to 180°.

Example embodiment 8 based on Example embodiment 7: the fifth angle is 60°.

Example embodiment 9 based on Example embodiment 7: the quantum dot transistor further includes a fifth plunger gate stack and a seventh barrier gate stack. The fifth plunger gate stack is disposed between the sixth barrier gate stack and the seventh barrier gate stack, the fifth plunger gate stack and the seventh barrier gate stack are arranged in a seventh straight axis, and there is a sixth angle between the sixth straight axis and the seventh straight axis is not equal to 180°.

Example embodiment 10 based on Example embodiment 9: the sixth angle is 60°.

Example embodiment 11 based on Example embodiment 9: the quantum dot transistor further includes a sixth plunger gate stack and an eighth barrier gate stack. The sixth plunger gate stack is disposed between the seventh barrier gate stack and the eighth barrier gate stack, the sixth plunger gate stack and the eighth barrier gate stack are arranged in an eighth straight axis, and there is a seventh angle between the seventh straight axis and the eighth straight axis is not equal to 180°.

Example embodiment 12 based on Example embodiment 11: the seventh angle A7 is 60°.

Example embodiment 13: a semiconductor device includes a substrate and a quantum dot transistor disposed on the substrate and includes a plurality of barrier gate stacks and a plurality of plunger gate stacks. The barrier gate stacks and the plunger gate stacks are arranged in a line, and the line is composed of a straight axis, a curved axis or a combination thereof.

Example embodiment 14 based on Example embodiment 13: the barrier gate stacks and the plunger gate stacks are arranged in a polygonal shape.

Example embodiment 15 based on Example embodiment 13: the line is a polygonal shape.

Example embodiment 16 based on Example embodiment 13: the line is an elliptical shape.

Example embodiment 17 based on Example embodiment 13: the semiconductor device includes a plurality of the quantum dot transistors, and the quantum dot transistors share one or some of the barrier gate stacks and one or some of the plunger gate stacks.

Example embodiment 18: a manufacturing method for a semiconductor device further includes the following steps: providing a substrate; and forming a quantum dot transistor on the substrate, wherein the quantum dot transistor includes a plurality of barrier gate stacks and a plurality of plunger gate stacks, wherein the barrier gate stacks and the plunger gate stacks are arranged in a line, and the line includes a straight axis, a curved axis or a combination thereof.

Example embodiment 19 based on Example embodiment 18: in forming the quantum dot transistor on the substrate, the barrier gate stacks and the plunger gate stacks are arranged in a polygonal shape.

Example embodiment 20 based on Example embodiment 18: in forming the quantum dot transistor on the substrate, a plurality of the quantum dot transistors share one or some of the barrier gate stacks and one or some of the plunger gate stacks.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate; and
a quantum dot transistor disposed on the substrate and comprising:
a first barrier gate stack;
a second barrier gate stack; and
a first plunger gate stack disposed between the first barrier gate stack and the second barrier gate stack;
wherein the first barrier gate stack and the first plunger gate stack are arranged in a first straight axis, the first plunger gate stack and the second barrier gate stack are arranged in a second straight axis, and there is a first angle between the first straight axis and the second straight axis is not equal to 180°.

2. The semiconductor device as claimed in claim 1, wherein the quantum dot transistor further comprises:
a second plunger gate stack; and
a third barrier gate stack;
wherein the second plunger gate stack is disposed between the second barrier and the third barrier gate stack, the second plunger gate stack and the third barrier gate stack are arranged in a third straight axis, and there is a second angle between the second straight axis and the third straight axis is not equal to 180°.

3. The semiconductor device as claimed in claim 1, wherein the quantum dot transistor further comprises:
a second plunger gate stack; and
a fourth barrier gate stack;
wherein the second plunger gate stack is disposed between the second barrier and the fourth barrier gate stack, the second plunger gate stack and the fourth barrier gate stack are arranged in a fourth straight axis, and there is a third angle between the second straight axis and the fourth straight axis is not equal to 180°.

4. The semiconductor device as claimed in claim 3, wherein the third angle is 60°.

5. The semiconductor device as claimed in claim 3, wherein the quantum dot transistor further comprises:
a third plunger gate stack; and
a fifth barrier gate stack;
wherein the third plunger gate stack is disposed between the fourth barrier gate stack and the fifth barrier gate stack, the third plunger gate stack and the fifth barrier gate stack are arranged in a fifth straight axis, and there is a fourth angle between the fourth straight axis S4 and the fifth straight axis is not equal to 180°.

6. The semiconductor device as claimed in claim 5, wherein the fourth angle is 60°.

7. The semiconductor device as claimed in claim 5, wherein the quantum dot transistor further comprises:
a fourth plunger gate stack; and
a sixth barrier gate stack;
wherein the fourth plunger gate stack is disposed between the fifth barrier gate stack and the sixth barrier gate stack, the fourth plunger gate stack and the sixth barrier gate stack are arranged in a sixth straight axis, and there is a fifth angle between the fifth straight axis and the sixth straight axis is not equal to 180°.

8. The semiconductor device as claimed in claim 7, wherein the fifth angle is 60°.

9. The semiconductor device as claimed in claim 7, wherein the quantum dot transistor further comprises:
a fifth plunger gate stack; and
a seventh barrier gate stack;
wherein the fifth plunger gate stack is disposed between the sixth barrier gate stack and the seventh barrier gate stack, the fifth plunger gate stack and the seventh barrier gate stack are arranged in a seventh straight axis, and there is a sixth angle between the sixth straight axis and the seventh straight axis is not equal to 180°.

10. The semiconductor device as claimed in claim 9, wherein the sixth angle is 60°.

11. The semiconductor device as claimed in claim 9, wherein the quantum dot transistor further comprises:
a sixth plunger gate stack; and
an eighth barrier gate stack;
wherein the sixth plunger gate stack is disposed between the seventh barrier gate stack and the eighth barrier gate stack, the sixth plunger gate stack and the eighth barrier gate stack are arranged in an eighth straight axis, and there is a seventh angle between the seventh straight axis and the eighth straight axis is not equal to 180°.

12. The semiconductor device as claimed in claim 11, wherein the seventh angle is 60°.

13. A semiconductor device, comprising:
a substrate; and
a quantum dot transistor disposed on the substrate and comprising:
a plurality of barrier gate stacks; and
a plurality of plunger gate stacks;
wherein the barrier gate stacks and the plunger gate stacks are arranged in a line, and the line is composed of a straight axis, a curved axis or a combination thereof.

14. The semiconductor device as claimed in claim 13, wherein the line is a polygonal shape.

15. The semiconductor device as claimed in claim 13, wherein the line is a circular shape.

16. The semiconductor device as claimed in claim 13, wherein the line is an elliptical shape.

17. The semiconductor device as claimed in claim 13, wherein the semiconductor device comprises a plurality of the quantum dot transistors, and the quantum dot transistors share one or some of the barrier gate stacks and one or some of the plunger gate stacks.

18. A manufacturing method for a semiconductor device, further comprising:
providing a substrate; and
forming a quantum dot transistor on the substrate, wherein the quantum dot transistor comprises a plurality of barrier gate stacks and a plurality of plunger gate stacks, wherein the barrier gate stacks and the plunger gate stacks are arranged in a line, and the line is composed of a straight axis, a curved axis or a combination thereof.

19. The manufacturing method as claimed in claim 18, wherein in forming the quantum dot transistor on the substrate, the barrier gate stacks and the plunger gate stacks are arranged in a polygonal shape.

20. The manufacturing method as claimed in claim 18, wherein in forming the quantum dot transistor on the substrate, a plurality of the quantum dot transistors share one or some of the barrier gate stacks and one or some of the plunger gate stacks.
